(19) United States
(12) Patent Application Publication
(10) Pub. No.: US 2024/0234215 A9
(43) Pub. Date: Jul. 11, 2024

(54) APPARATUS FOR MEASURING AN ADHESION FORCE

(71) Applicant: SAMSUNG ELECTRONICS CO., LTD., Suwon-si (KR)

(72) Inventors: Donggap SHIN, Suwon-si (KR); Yongin LEE, Suwon-si (KR); Wooyoung KIM, Suwon-si (KR); Bumki MOON, Suwon-si (KR); Jiwon MOON, Suwon-si (KR); Seungdae SEOK, Suwon-si (KR); Siwoong WOO, Suwon-si (KR); Byeongtak PARK, Suwon-si (KR)

(21) Appl. No.: 18/139,674

(22) Filed: Apr. 26, 2023

(30) Foreign Application Priority Data
Oct. 21, 2022 (KR) 10-2022-0136500

(51) Int. Cl. H01L 21/66; H01L 23/00

(52) U.S. Cl. CPC H01L 22/12; H01L 24/74; H01L 24/80; H01L 24/08; H01L 2224/08145; H01L 2224/74; H01L 2224/8001; H01L 2224/80894; H01L 2224/80908; H01L 2924/3511; H01L 2924/35121; H01L 2924/401

(57) ABSTRACT

An apparatus for measuring an adhesion force, the apparatus comprising a stage configured to support a specimen, and a sensor adhered to the specimen, wherein the sensor detects the adhesion force of the specimen, the adhesion force of the specimen being a force for detaching the sensor from the specimen.

### CROSS-REFERENCE TO RELATED APPLICATION

Korean Patent Application No. 10-2022-0136500, filed on Oct. 21, 2022, in the Korean Intellectual Property Office, the contents of which are herein incorporated by reference in their entirety.

### BACKGROUND

### 1. Field

Example embodiments relate to an apparatus for measuring an adhesion force.

### 2. Description of the Related Art

Processes for bonding two wafers with semiconductor chips may include a hybrid bonding process not using an adhesive.

### SUMMARY

Embodiments are directed to an apparatus for measuring an adhesion force. The apparatus may include a stage configured to support a specimen, and a sensor adhered to the specimen, wherein the sensor detects the adhesion force of the specimen, the adhesion force of the specimen being a force for detaching the sensor from the specimen.

Embodiments are also directed to an apparatus for measuring an adhesion force. The apparatus may include a stage configured to support a specimen, a first horizontal actuator configured to move the stage in a first horizontal direction, a second horizontal actuator configured to move the stage in a second horizontal direction substantially perpendicular to the first horizontal direction, a sensor adhered to the specimen, and an imager configured to obtain an image of the specimen. The sensor may detect a force for detaching the sensor from the specimen as the adhesion force of the specimen. Embodiments are also directed to an apparatus for measuring an adhesion force. The apparatus may include a surface treatment apparatus configured to process surfaces of a plurality of wafers, an adhesion force measurement apparatus configured to measure an adhesion force of each of the wafers processed by the surface treatment apparatus, and a bonding apparatus configured to hybrid bond the wafers to each other.

### BRIEF DESCRIPTION OF THE DRAWINGS

Features will become apparent to those of skill in the art by describing in detail exemplary embodiments with reference to the attached drawings in which:

FIG. 1 is a plan view illustrating a wafer bonding system in accordance with example embodiments.

FIGS. 2 to 6 are views of stages in a process for treating a surface of a wafer by a surface treatment apparatus of the wafer bonding system.

FIG. 7 is a graph showing an adhesion force of a wafer before and after being processed by the surface treatment apparatus in.

FIG. 8 is a graph showing a relation between an adhesion force of a wafer and a bonding strength of bonded wafers.

FIG. 9 is a view illustrating an adhesion force measurement apparatus.

FIGS. 10 to 15 are views illustrating operations of the adhesion force measurement apparatus.

FIG. 16 is a graph showing changes of forces applied to a wafer by the adhesion force measurement apparatus.

FIG. 17 is a view illustrating adhesion forces by regions of a wafer measured by the adhesion force measurement apparatus.

FIG. 18 is a view illustrating an adhesion force measurement apparatus in accordance with example embodiments.

### DETAILED DESCRIPTION

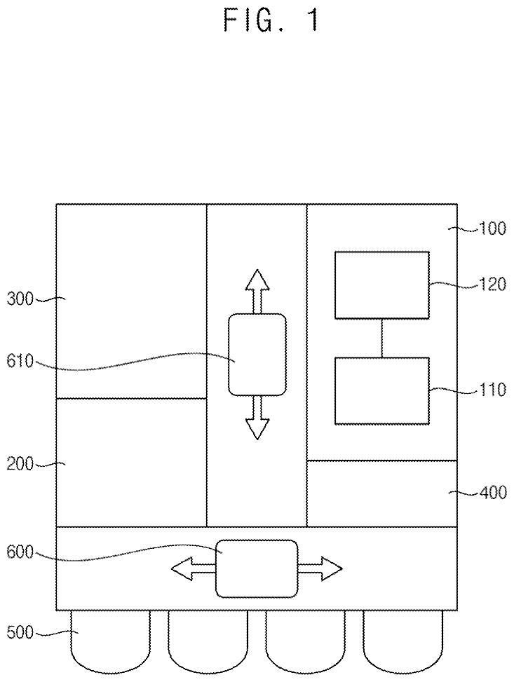

FIG. 1 is a plan view illustrating a wafer bonding system in accordance with example embodiments.

Referring to FIG. 1, a wafer bonding system of example embodiments may bond two wafers W to each other by a hybrid bonding process. The wafer bonding system may include a surface treatment apparatus 100, an adhesion force measurement apparatus 200 and a bonding apparatus 300.

The surface treatment apparatus 100 may face the adhesion force measurement apparatus 200 and the bonding apparatus 300. The surface treatment apparatus 100 may be spaced apart from the adhesion force measurement apparatus 200 and the bonding apparatus 300 to allow for a transfer space between the surface treatment apparatus 100 and the adhesion force measurement apparatus 200 and the bonding apparatus 300. A second robot 610 may be in the transfer space. Further, the adhesion force measurement apparatus 200 and the bonding apparatus 300 may be sequentially arranged. Additionally, an alignment apparatus 400 may be positioned adjacent to the surface treatment apparatus 100.

The wafers W may be received in a Front Opening Unified Pod (FOUP) 500. A first robot 600 may transfer the wafers W in the FOUP 500 to the second robot 610. The second robot 610 may load the wafers W into the alignment apparatus 400. The alignment apparatus 400 may align the wafers W for a surface treatment process. The surface treatment process may occur after the alignment process.

The surface treatment apparatus 100 may include a plasma-processor 110 and a cleaner 120. The plasma-processor 110 may process a surface of the wafer W using plasma. The cleaner 120 may clean the surface of the wafer W processed by the plasma using a rinse solution.

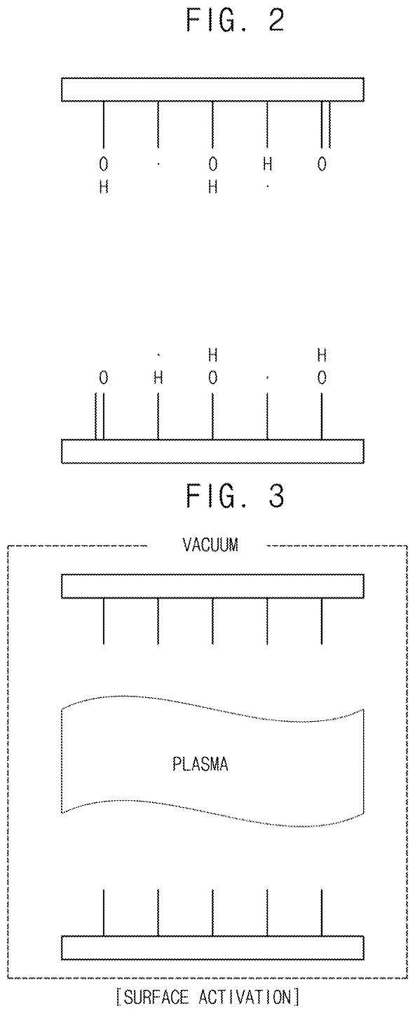

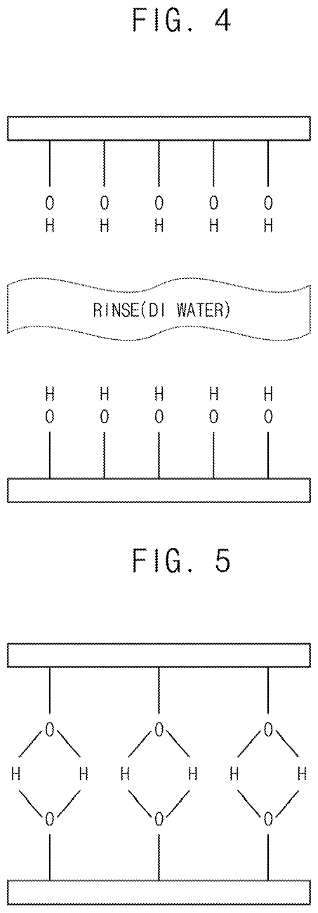

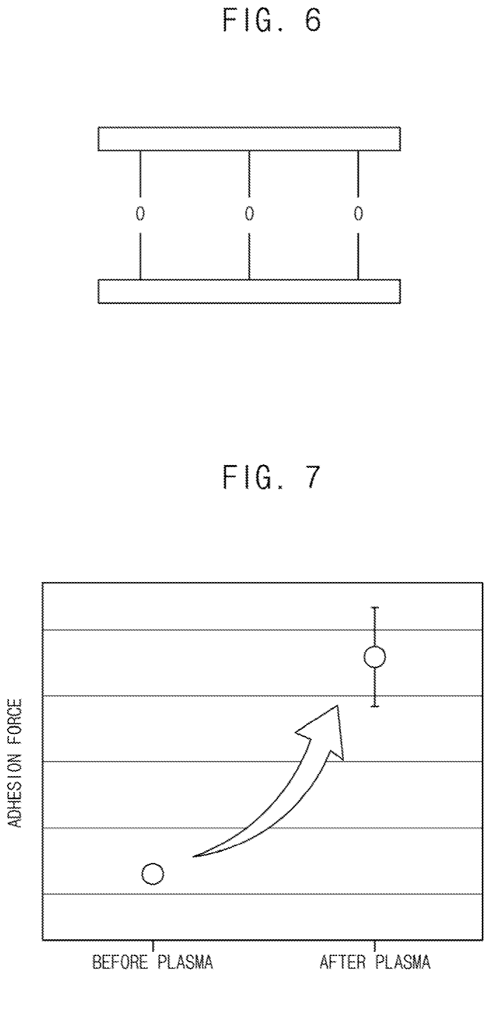

FIGS. 2 to 6 are views illustrating a process for treating a surface of a wafer by a surface treatment apparatus of the wafer bonding system. Referring to FIGS. 2 to 6, the plasma may be applied to the surface of the wafer W to form dangling bonds on the surface of the wafer W. OH groups generated by the plasma process and the cleaning process may generate a condensation reaction between the contacted wafers W. The wafers W may then be annealed, the wafers W may be covalently bonded to each other.

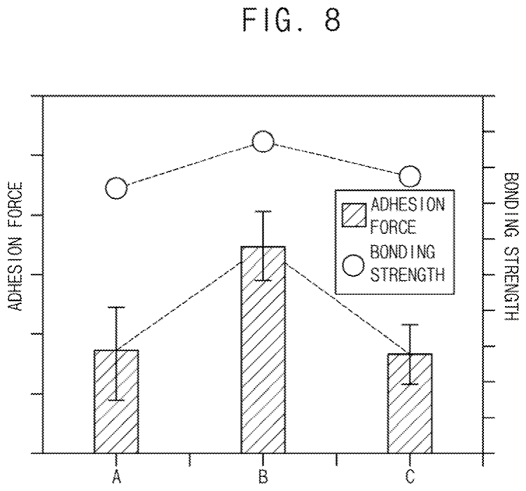

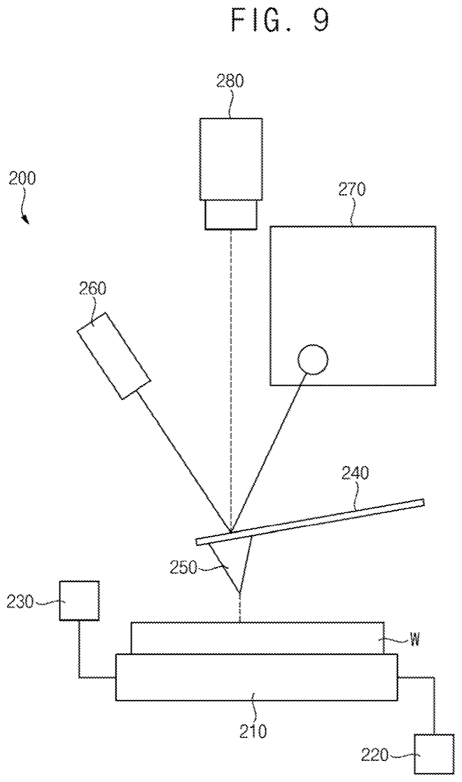

FIG. 7 is a graph showing an adhesion force of a wafer before and after being processed by the surface treatment apparatus. As shown in FIG. 7, it can be noted that an adhesion force after processing the surface of the wafer W using the plasma may be greatly increased compared to an adhesion force before processing the surface of the wafer W using the plasma.

FIG. 8 is a graph showing a relation between an adhesion force of a wafer and a bonding strength of bonded wafers. As shown in FIG. 8, the adhesion force of the wafer W before the bonding process may be proportional to a bonding strength of bonded wafers W. Thus, the bonding strength of the bonded wafers W may be recognized by measuring the adhesion force of the wafer W before the bonding process.

FIG. 9 is a view illustrating an adhesion force measurement apparatus. Referring to FIG. 9, the adhesion force measurement apparatus 200 may measure the adhesion force of the wafer W before the bonding process by a non-destructive test. The adhesion force measurement apparatus 200 may include a stage 210, a sensor and an imager 280.

A specimen, e.g., the wafer W may be placed on an upper surface of the stage 210. A first horizontal actuator 220 may be configured to move the stage 210 in a first horizontal direction. A second horizontal actuator 230 may be configured to move the stage 210 in a second horizontal direction substantially perpendicular to the first horizontal direction. The first horizontal actuator 220 and the second horizontal actuator 230 may include a motor, or a cylinder.

The adhesion forces by regions of the wafer W on the stage 210 may be measured by moving the stage 210 in the first and second horizontal directions by the first and second horizontal actuators 220 and 230.

The imager 280 may be over the stage 210. The imager 280 may obtain an image of the wafer W on the stage 210. A position of the sensor and a position of the wafer W may be recognized based on the image. The imager 280 may include an optical microscope, or a camera.

The sensor may be adhered to the wafer W. The sensor may detect a force for detaching the sensor from the wafer W. In order to detach the sensor from the wafer W, it may be required to apply a force of no less than the adhesion force of the wafer to the sensor. Thus, the force for detaching the sensor from the wafer W may correspond to the adhesion force of the wafer W.

In an implementation, the sensor may include a cantilever 240, a probe 250 and an optical sensing portion. The cantilever 240 may be arranged over the stage 210. In an implementation, the cantilever 240 may be rotated with respect to a horizontal axis. The probe 250 may be arranged at a lower end of the cantilever 240. The probe 250 may selectively make contact with the surface of the wafer W on the stage 210 by rotations of the cantilever 240. Thus, the probe 250 may be adhered to the surface of the wafer W.

The optical sensing portion may detect a bending of the cantilever 240 by a force for detaching the probe 250 from the surface of the wafer W. The bending of the cantilever 240 may correspond to the force for detaching the probe 250 from the surface of the wafer W so that the bending of the cantilever 240 may be the adhesion force of the wafer W.

The optical sensing portion may include an emitter 260 and an optical detector 270. The emitter 260 may be arranged at a left upper region of the cantilever 240. The emitter 260 may irradiate a light to the cantilever 240. In an implementation, the light may include a laser. The optical detector 270 may be arranged at a right upper region of the cantilever 240. The optical detector 270 may detect a light reflected from the cantilever 240. The reflected light detected by the optical detector 270 may include information with respect to the bending of the cantilever 240 so that the bending of the cantilever 240 may be recognized based on the information of the reflected light.

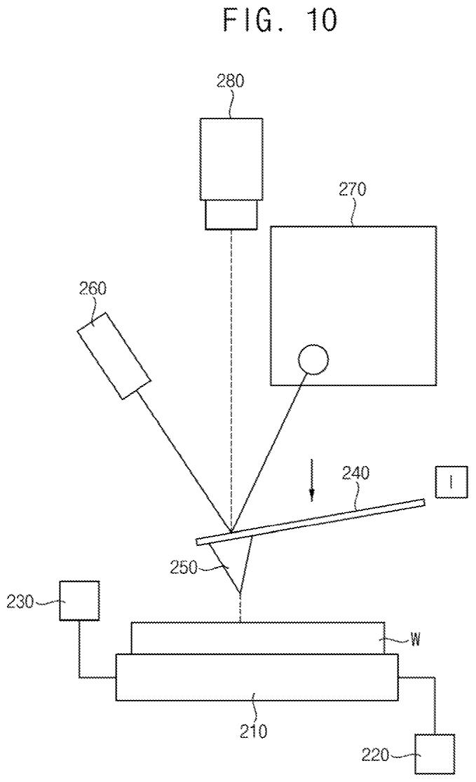

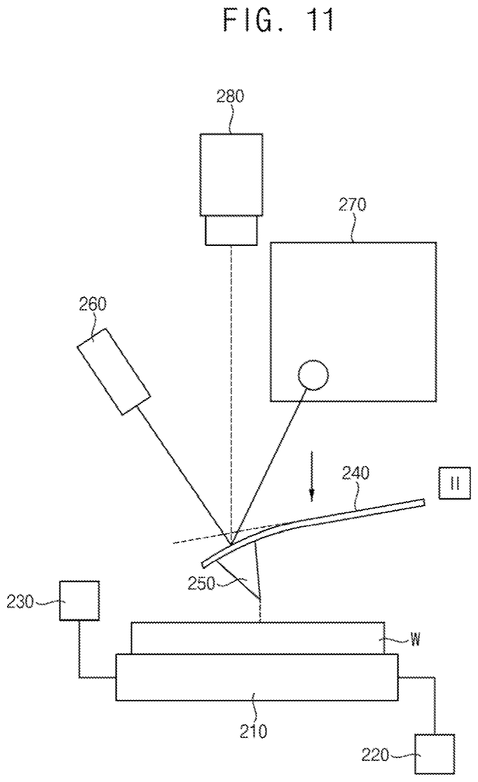

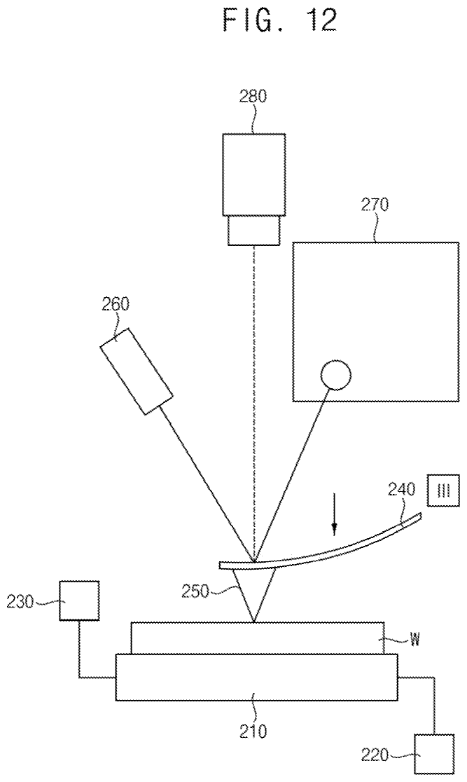

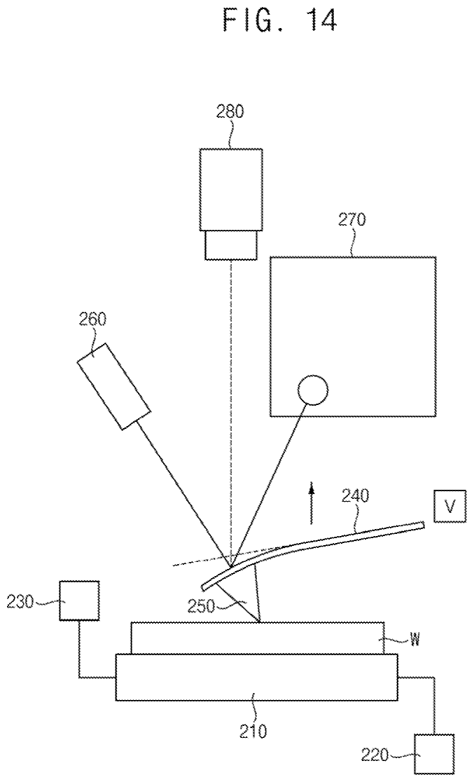

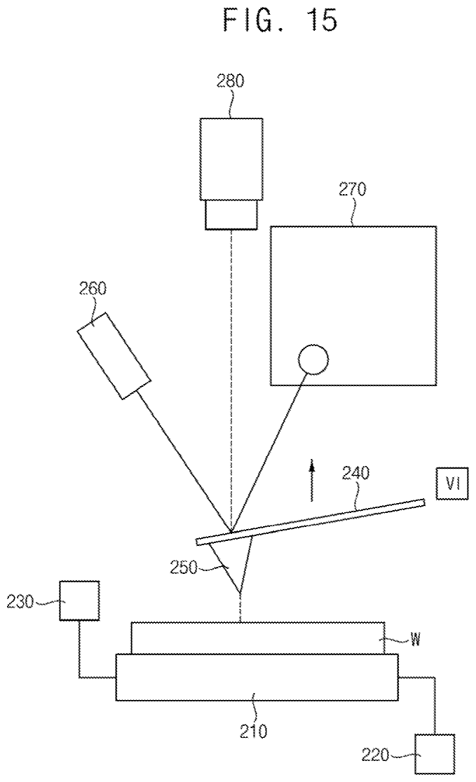

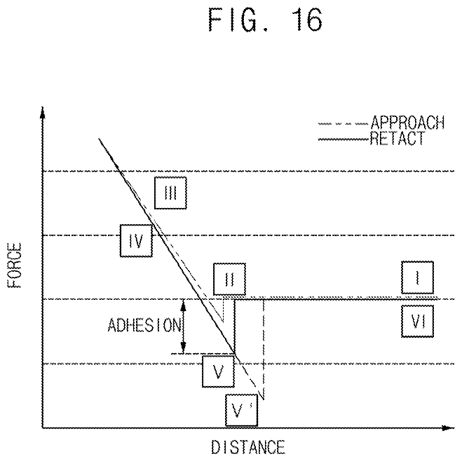

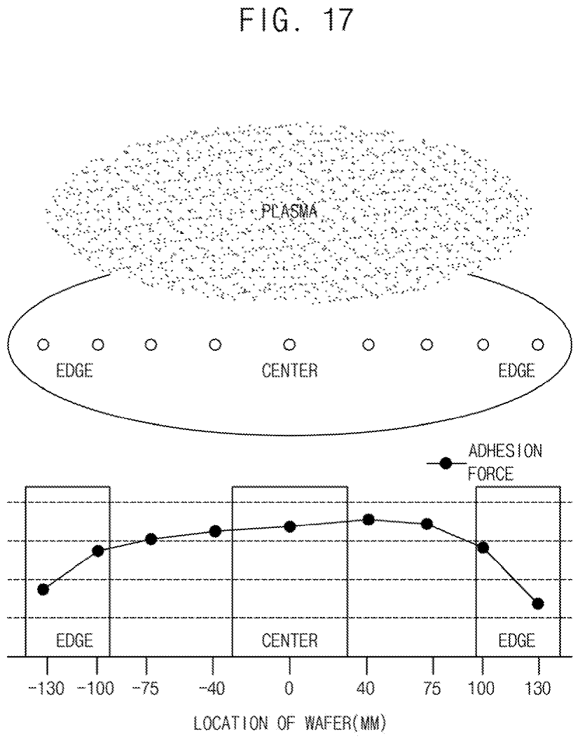

FIGS. 10 to 15 are views illustrating operations of the adhesion force measurement apparatus in FIG. 9 and FIG. 16 is a graph showing changes of forces applied to a wafer by the adhesion force measurement apparatus in FIG. 9.

Referring to FIGS. 12 to 15 and 16, when the cantilever 240 gradually approaches the surface of the wafer W, the force applied to the probe 250 may be sharply increased. However, in FIG. 11, the force applied to the probe 250 may be slightly decreased. This may be caused by a snap-in by an attractive force between the probe 250 and the wafer W. When the probe 250 makes contact with the surface of the wafer W, the probe 250 may be adhered to the surface of the wafer W by the adhesion force of the wafer W.

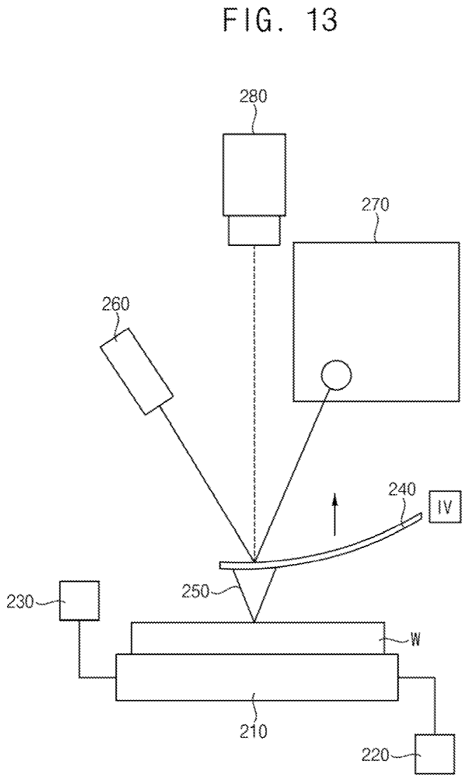

In contrast, referring to FIGS. 13 to 16, when the cantilever 240 is retracted from the surface of the wafer W, the probe 250 may not be detached from the surface of the wafer W during a force below the adhesion force of the wafer W which may be applied to the cantilever 240. When a force of no less than the adhesion force of the wafer W is applied to the cantilever 240, the probe 250 may then be detached from the surface of the wafer W.

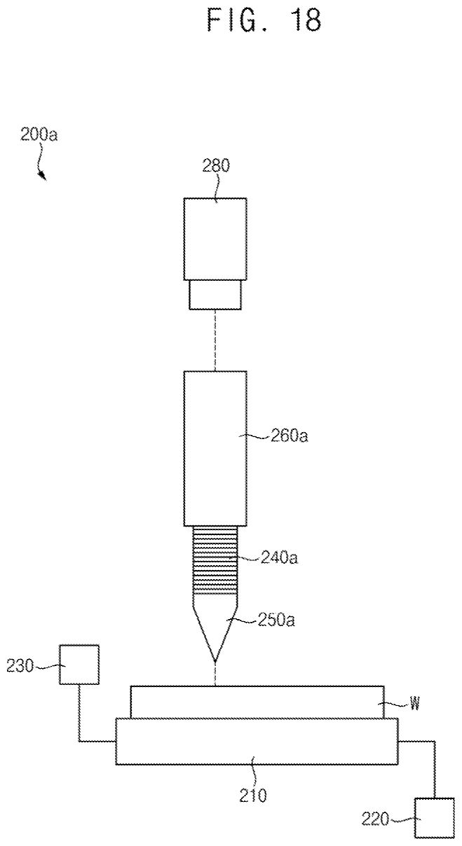

FIG. 17 is a view illustrating adhesion forces by regions of a wafer measured by the adhesion force measurement apparatus. As shown in FIG. 17, an adhesion force of a central portion of the wafer W having a high density of the plasma may be higher than an adhesion force of an edge portion of the wafer W having a low density of the plasma. Thus, a density distribution of the plasma may be obtained based on the adhesion forces by the regions of the wafer W measured by the adhesion force measurement apparatus 200.

FIG. 18 is a view illustrating an adhesion force measurement apparatus in accordance with example embodiments. An adhesion force measurement apparatus 200a of example embodiments may include elements substantially the same as those of the adhesion force measurement apparatus 200 in FIG. 9 except for a sensor. Thus, the same reference numerals may refer to the same elements and any further illustrations with respect to the same elements may be omitted herein for brevity.

Referring to FIG. 18, a sensor of example embodiments may include a force sensing portion 240a, a probe 250a and a vertical actuator 260a. The force sensing portion 240a may be vertically arranged over the stage 210. The probe 250a may be arranged at a lower end of the force sensing portion 240a. The vertical actuator 260a may be connected to an upper end of the force sensing portion 240a.

The vertical actuator 260a may move the force sensing portion 240a and the probe 250a in the vertical direction. Thus, the probe 250a may selectively make contact with the surface of the wafer W on the stage 210. In an implementation, the probe 250a may be adhered to the surface of the wafer W.

The force sensing portion 240a may measure a force for detaching the probe 250a from the surface of the wafer W. As mentioned above, the force for detaching the probe 250a from the surface of the wafer W may correspond to the adhesion force of the wafer W so that the force measured by the force sensing portion 240a may correspond to the adhesion force of the wafer W.

In an implementation, the bonding system may be applied to the bonding process of the wafers. In an implementation, the bonding system may also be applied to a process for bonding a semiconductor chip to a wafer, a process for bonding semiconductor chips to each other.

According to example embodiments, the sensor may measure the force for detaching a probe from the specimen such as the wafer. The force may correspond to the adhesion force of the specimen. Thus, before bonding the wafers, the adhesion force of the wafer may be accurately measured. Adhesion strength of the bonded wafer may be obtained from the adhesion force of the wafer, and a scrapping of the wafer may be prevented. Further, because it may not be required to manufacture a wafer specimen for measuring the adhesion force of the bonded wafers, a time for bonding the wafer may be reduced.

By way of summation and review, example embodiments relate to an apparatus for measuring an adhesion force of a wafer bonded by a hybrid bonding process and a wafer bonding system including the apparatus.

The wafers bonded by the hybrid bonding process may require strong bonding strength capable of preventing a delamination of the wafers by a force, a warpage, or a surface stress, in a following process. Thus, it may be required to measure the bonding strength of the wafers.

The bonding strength of the bonded wafers may be measured by a double cantilever beam way. The double cantilever beam way may insert a blade between the wafers to measure a gap between the wafers.

However, in order to insert the blade, the wafers may be splayed so that the wafers used for measuring the bonding strength may be scrapped. Further, it may be required to manufacture an additional wafer specimen for the double cantilever beam way. Example embodiments provide an apparatus for measuring an adhesion force of a specimen such as a wafer before a bonding process. Example embodiments also provide a wafer bonding system including the above-mentioned apparatus.

According to example embodiments, the sensor may measure the force for detaching a probe from the specimen such as the wafer. The force may correspond to the adhesion force of the specimen. Thus, before bonding the wafers, the adhesion force of the wafer may be accurately measured. Because adhesion strength of the bonded wafer may be obtained from the adhesion force of the wafer, a scrapping of the wafer may be prevented. Further, because it may not be required to manufacture a wafer specimen for measuring the adhesion force of the bonded wafers, a time for bonding the wafer may be reduced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An apparatus for measuring an adhesion force, the apparatus comprising:
a stage configured to support a specimen; and
a sensor adhered to the specimen,
wherein the sensor detects the adhesion force of the specimen, the adhesion force of the specimen being a force for detaching the sensor from the specimen.

2. The apparatus as claimed in claim 1, wherein the sensor includes:
a cantilever arranged over the stage;
a probe arranged at the cantilever and adhered to the specimen; and
an optical sensing portion configured to detect a bending of the cantilever by a force for detaching the probe from the specimen.

3. The apparatus as claimed in claim 2, wherein the optical sensing portion includes:
an emitter configured to irradiate a light to the cantilever; and
an optical detector configured to detect a light reflected from the cantilever.

4. The apparatus as claimed in claim 3, wherein the light includes a laser.

5. The apparatus as claimed in claim 1, wherein the sensor includes:
a probe adhered to the specimen;
a vertical actuator configured to vertically move the probe; and
a force sensing portion configured to detect a force for detaching the probe from the specimen.

6. The apparatus as claimed in claim 1, further comprising an imager configured to obtain an image of the specimen.

7. The apparatus as claimed in claim 6, wherein the imager includes an optical microscope or a camera.

8. The apparatus as claimed in claim 1, further including:
a first horizontal actuator configured to move the stage in a first horizontal direction; and
a second horizontal actuator configured to move the stage in a second horizontal direction substantially perpendicular to the first horizontal direction.

9. The apparatus as claimed in claim 1, wherein the specimen includes a wafer or a semiconductor chip.

10. An apparatus for measuring an adhesion force, the apparatus comprising:
a stage configured to support a specimen;
a first horizontal actuator configured to move the stage in a first horizontal direction;
a second horizontal actuator configured to move the stage in a second horizontal direction substantially perpendicular to the first horizontal direction;
a sensor adhered to the specimen; and
an imager configured to obtain an image of the specimen,
wherein the sensor detects a force for detaching the sensor from the specimen as the adhesion force of the specimen.

11. The apparatus as claimed in claim 10, wherein the sensor includes:
a cantilever arranged over the stage;
a probe arranged at the cantilever and adhered to the specimen; and
an optical sensing portion configured to detect a bending of the cantilever by a force for detaching the probe from the specimen.

12. The apparatus as claimed in claim 11, wherein the optical sensing portion includes:
an emitter configured to irradiate a light to the cantilever; and
an optical detector configured to detect a light reflected from the cantilever.

13. The apparatus as claimed in claim 10, wherein the sensor includes:
a probe adhered to the specimen;
a vertical actuator configured to vertically move the probe; and
a force sensing portion configured to detect a force for detaching the probe from the specimen.

14. An apparatus for measuring an adhesion force, the apparatus comprising:
a surface treatment apparatus configured to process surfaces of a plurality of wafers;
an adhesion force measurement apparatus configured to measure an adhesion force of each of the wafers processed by the surface treatment apparatus; and
a bonding apparatus configured to hybrid bond the wafers to each other.

15. The apparatus as claimed in claim 14, wherein the surface treatment apparatus includes:
a plasma-processor configured to process the surfaces of the wafers using plasma; and
a cleaner configured to clean the surfaces of the wafers.

16. The apparatus as claimed in claim 14, wherein the adhesion force measurement apparatus includes:
a stage configured to support each of the wafers; and
a sensor adhered to the specimen,
wherein the sensor detects a force for detaching the sensor from the specimen as the adhesion force of the wafer.

17. The apparatus as claimed in claim 16, wherein the sensor includes:
a cantilever arranged over the stage;
a probe arranged at the cantilever and adhered to the specimen; and
an optical sensing portion configured to detect a bending of the cantilever by a force for detaching the probe from the wafer.

18. The apparatus as claimed in claim 17, wherein the optical sensing portion includes:
an emitter configured to irradiate a light to the cantilever; and
an optical detector configured to detect a light reflected from the cantilever.

19. The apparatus as claimed in claim 16, wherein the sensor includes:
a probe adhered to the wafer;
a vertical actuator configured to vertically move the probe; and
a force sensing portion configured to detect a force for detaching the probe from the wafer.

20. The apparatus as claimed in claim 16, wherein the adhesion force measurement apparatus further includes:
an imager configured to obtain an image of the wafer;
a first horizontal actuator configured to move the stage in a first horizontal direction; and
a second horizontal actuator configured to move the stage in a second horizontal direction substantially perpendicular to the first horizontal direction.
